(19) United States
(12) Patent Application Publication
(10) Pub. No.: US 2002/0093097 A1
(43) Pub. Date: Jul. 18, 2002

(54) Semiconductor device

(75) Inventors: Takao Kamoshima, Tokyo (JP); Takashi Yamashita, Tokyo (JP); Yoshifumi Takata, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 09/910,827

(22) Filed: Jul. 24, 2001

(30) Foreign Application Priority Data
Jan. 17, 2001 (JP) 2001-009460

(51) Int. Cl. H01L 23/48

(52) U.S. Cl. 257/751

(57) ABSTRACT

There is provided a W plug formation method which prevents occurrence of a clearance or void around a W plug after HF cleansing as well as occurrence of an increase in resistance of a via hole and that of a contact hole, and occurrence of open failures. A surface layer section of a Ti film-which has been formed as barrier metal film in a hole formed in an interlayer dielectric film on a lower interconnection-is oxidized by means of oxygen plasma processing, thereby forming a Ti oxide film. Thus, the surface of the Ti film is not exposed on the surface. There can be prevented elution of the Ti film, which would otherwise be caused by HF cleansing effected in a subsequent process, and occurrence of a clearance or void, which would otherwise arise around a conductive plug.

### BACKGROUND OF THE INVENTION

1. Field of the Invention

The present invention relates to a semiconductor device and a method of manufacturing the semiconductor device, and more particularly, to an interconnection structure of a semiconductor device and a method of forming the interconnection structure.

2. Background Art

In a semiconductor device formed into a multilayer structure, two different metal interconnection layers are electrically interconnected by way of a connection hole (a via hole for interconnecting metal interconnections, or a contact hole for connecting a metal interconnection and a polysilicon layer or diffusion layer) formed in an interlayer dielectric film formed on a substrate. The connection hole is embedded with metal; e.g., tungsten (W), and a plug of conductive film (hereinafter called a “W plug”) is formed.

As approaches to smooth the surf ace of an interconnection structure of such a semiconductor device at the time of formation of a W plug, there have primarily been employed an approach involving etch back and an approach involving chemical-and-mechanical polishing (CMP). Etch back is a technique wherein, on a pattern having a step stemming from embedding of tungsten (W), a dielectric film which is of greater thickness than the step is formed by means of chemical vapor deposition (CVD), and the dielectric film is etched, thereby smoothing the surface of the dielectric film.

CMP is a technique wherein, a pattern having a step stemming from embedding of tungsten (W) is brought into contact with an abrasion pad provided on the surface of a turntable and the pattern is abraded, thereby smoothing the surface of the pattern. In contrast with etch back, CMP does not involve a necessity of embedding a plug recess which arises in a metal interconnection after formation of a W plug. Even in terms of a reduction in extraneous substance, CMP is advantageous and hence is now becoming predominant.

Hydrofluoric acid cleansing (HF cleansing), which is to be effected after abrasion of a pattern through CMP for removing metal contaminants and extraneous matter, is less costly. Further, HF cleansing, which is very easy to manage, is primarily used for post cleansing. However, CMP has yielded various problems such as those mentioned below.

FIG. 18 is a cross-sectional view showing a structure of a semiconductor device immediately before being subjected to CMP; i.e., after having been subjected to deposition through CVD (i.e., deposition of a metal film). As shown in FIG. 18, reference numeral 1 designates a lower interconnection; 2 designates an interlayer dielectric film; 3 designates a titanium (Ti) film; 4 designates a titanium nitride film (TiN) film; and 5 designates a tungsten (W) film deposited as a result of CVD (CVD for deposition of W will hereinafter be referred to as “W-CVD”).

FIG. 18 shows a structure which has been formed in accordance with the following processes. First, after an interlayer dielectric film 2 has been formed on a lower interconnection 1, a hole is formed in the interlayer dielectric film 2 by means of dry etching. The Ti film 3 and the TiN film 4 are formed in sequence from the interlayer dielectric film 2, as barrier metal film, on the interlayer dielectric film 2 including the hole 6. Formation of the Ti film 3 and the TiN film 4 is for preventing formation of another phase, which would otherwise be caused by diffusion or reaction arising between different metal films, or for enhancing contact between the interlayer dielectric film 2 and the W film 5. The W film 5 is deposited on the Ti film 3 and the TiN film 4 so as to fill the hole 6.

FIG. 19 is a cross-sectional view showing the structure of a semiconductor device immediately after W has been abraded through CMP (this processing will hereinafter be called “W-CMP”). In FIG. 19, elements which are identical with those shown in FIG. 18 are assigned the same reference numerals. Reference numeral 7 designates a W film smoothed by abrasion. The W film 7 acts as a conductive W plug.

FIG. 20 is a cross-sectional view showing the result of HF cleansing of the semiconductor device after the semiconductor device has been subjected to W-CMP. In FIG. 20, elements which are identical with those shown in FIG. 19 are assigned the same reference numerals. As shown in FIG. 20, hydrofluoric (HF) acid vigorously dissolves titanium (Ti). Hence, a clearance 9 arises in the Ti film 3, and a recess arises in the oxide film (the interlayer dielectric film 2) located around the clearance 9. In the worst scenario, the lower interconnection 1 is also dissolved, thereby inducing generation of a macroscopic void 10 in the interconnection film. As a result, an increase in resistance of a via hole or contact hole and open failures arise.

The present invention has been conceived to solve such a problem and is aimed at providing a W plug formation method which prevents occurrence of a clearance or a void around a W plug after HF cleansing and occurrence of an increase in resistance of a via hole or contact hole and open failures.

### SUMMARY OF THE INVENTION

According to one aspect of the present invention, a semiconductor device comprises a substrate, an interlayer dielectric film formed on or above the substrate, a lower conductive layer formed in or on the substrate under or below the interlayer dielectric film, a conductive plug formed to embed a connection hole being formed in the interlayer dielectric film, and a barrier metal film formed between the conductive plug and the interlayer dielectric film and between the conductive plug and the lower conductive layer. At least a portion of the barrier metal film is formed from metal having elution resistance against hydrofluoric acid.

According to another aspect of the present invention, a semiconductor device comprises a substrate, an antireflection film formed on or above the substrate, an interlayer dielectric film formed on the antireflection film, a lower conductive layer formed in or on the substrate under or below the antireflection film, a conductive plug formed to embed a connection hole being formed in the antireflection film and the interlayer dielectric film, and a barrier metal film formed between the conductive plug and the antireflection film and between the conductive plug and the interlayer dielectric film. The bottom of the connection hole is formed within the antireflection film, and at least a portion of the barrier metal film is formed from metal having elution resistance against hydrofluoric acid.

Other and further objects, features and advantages of the invention will appear more fully from the following description.

### BRIEF DESCRIPTION OF THE DRAWINGS

FIG. 1 is a cross-sectional view of a structure after having been subjected to W-CMP, showing a semiconductor device according to a first embodiment of the present invention.

FIG. 2 is a cross-sectional view of a structure after having been subjected to W-CMP, showing a semiconductor device according to a second embodiment of the present invention.

FIG. 3 is a cross-sectional view of a structure before being subjected to W-CMP, showing a semiconductor device according to a third embodiment of the present invention.

FIGS. 4 through 7 show a semiconductor device according to a fourth embodiment of the present invention.

FIGS. 8 and 9 show a semiconductor device according to a fifth embodiment of the present invention.

FIGS. 10 through 14 show a semiconductor device according to a sixth embodiment of the present invention.

FIGS. 15 through 17 show a semiconductor device according to a seventh embodiment of the present invention.

FIGS. 18 through 20 are a cross-sectional view showing a structure of a conventional semiconductor device.

### DETAILED DESCRIPTION OF THE PREFERRED EMBODIMENTS

Preferred embodiments of the present invention will be described hereinbelow by reference to the drawings.

First Embodiment

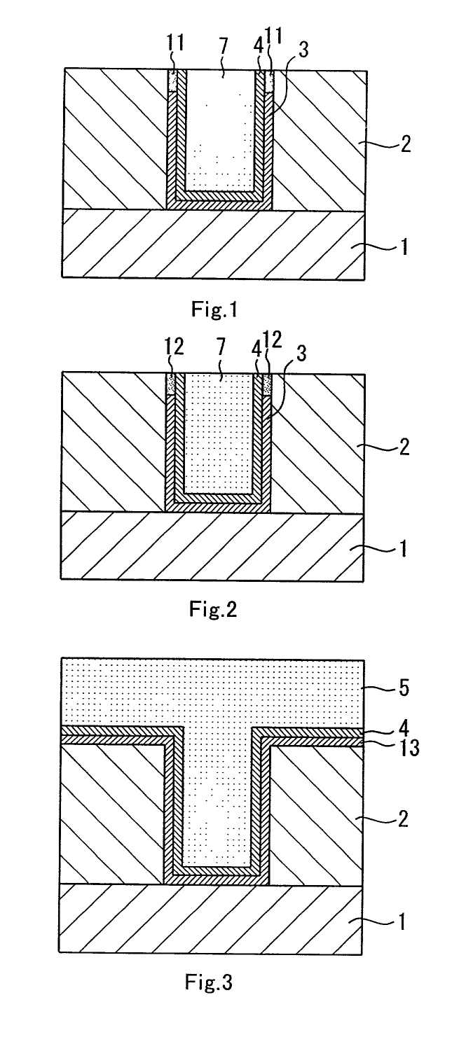

FIG. 1 is a cross-sectional view of a structure after having been subjected to W-CMP, showing a semiconductor device according to a first embodiment of the present invention. As shown in FIG. 1, reference numeral 1 designates a lower interconnection (a lower conductive layer); 2 designates an interlayer dielectric film; 3 designates a titanium (Ti) film; 4 designates a titanium nitride (TiN) film; 7 designates a tungsten (W) film; and 11 designates a Ti oxide film.

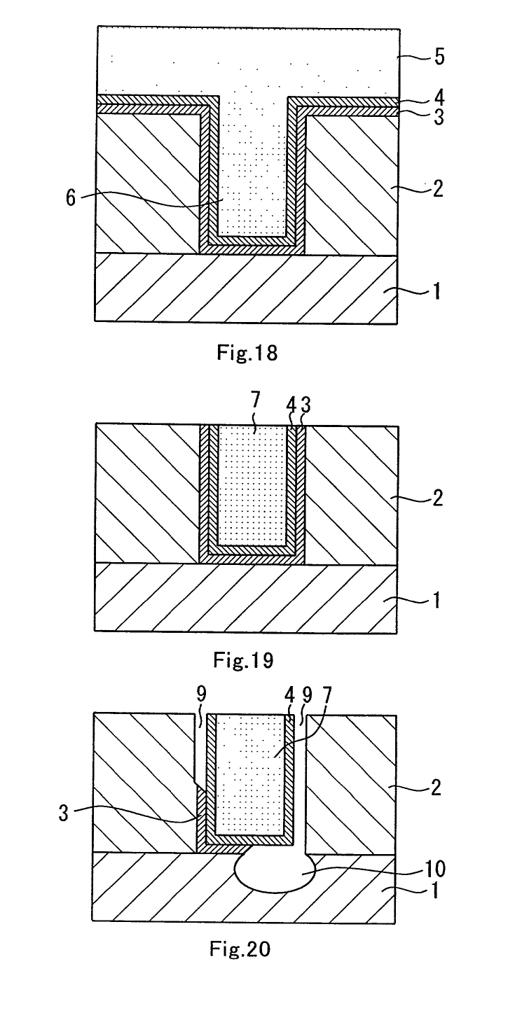

The W plug structure shown in FIG. 1 is formed through the following processes. Specifically, after the interlayer dielectric film 2 has been formed on the lower interconnection 1, a hole (in which the W film 7 is to be formed) is formed in the interlayer dielectric film 2 by means of dry etching. The Ti film 3 and the TiN film 4 are formed in sequence from the interlayer dielectric film 2, as barrier metal film, on the interlayer dielectric film 2 including the hole. The W film 7 is deposited on the Ti film 3 and the TiN film 4 by means of CVD so as to fill the hole (see FIG. 18).

An excessive W film deposited on the interlayer dielectric film 2 is removed by abrasion through CMP. As a result, the W film 7 is left in the hole, thus constituting a W plug (see FIG. 19). After having been abraded through W-CMP and before being subjected to HF cleansing, a semiconductor device is subjected to 02 (oxygen) plasma processing or heat treatment, such as annealing, in an 02 atmosphere. As a result, a surface layer section of the Ti film 3 is oxidized, thereby forming a Ti oxide film 11. Accordingly, the surface of the Ti film 3 is not exposed.

In the first embodiment, at least a surface section of the Ti film 3 is oxidized, thereby forming the Ti oxide film 11 and preventing the Ti film 3 from becoming exposed on the surface. Accordingly, there can be prevented elution of the Ti film 3, which would otherwise be caused by HF cleansing, and occurrence of a clearance or void, which would otherwise arise around the W plug. The present embodiment can be applied to either of a contact hole and a via hole.

Second Embodiment

FIG. 2 is a cross-sectional view of a structure after having been subjected to W-CMP, showing a semiconductor device according to a second embodiment of the present invention. As shown in FIG. 2, reference numeral 1 designates a lower interconnection; 2 designates an interlayer dielectric film; 3 designates a titanium (Ti) film; 4 designates a TiN film; 7 designates a tungsten (W) film; and 12 designates a TiN film. Procedures required for forming the lower interconnection 1, the interconnection dielectric film 2, the Ti film 3, the TiN film 4, and the W film-7 are the same as those described by reference to FIG. 1.

In the present embodiment, after having been abraded through W-CMP and before being subjected to HF cleansing, the semiconductor device is subjected to N₂ (nitrogen) plasma processing or annealing in an N₂ atmosphere at a temperature of 600° C. or more. As a result, a surface layer portion of the Ti film 3 is nitrided, thereby forming a TiN film 12 and preventing exposure of the Ti film 3 on the surface. Alternatively, the semiconductor device may be subjected to NH₃ (ammonia) plasma processing or annealing in an NH₃ atmosphere at a temperature of 600° C. or more.

According to the second embodiment, the TiN film 12 is formed by means of nitriding at least a surface layer portion of the Ti film 3, thereby preventing the Ti film 3 from being exposed on the surface. Accordingly, there can be prevented elution of Ti film 3, which would otherwise be caused by HF cleansing, and occurrence of a clearance or void, which would otherwise arise around the W plug.

The surface of the interlayer dielectric film 2 is also nitrided, thereby preventing etching of the interlayer dielectric film 2, which would otherwise be caused by HF cleansing. As a result, there can be prevented extension of etching to the portion of the Ti film 3 which has not been nitrided. Thus, there can be reliably prevented occurrence of a problem, such as occurrence of a clearance or void, which would otherwise arise around a conductive plug (W plug). The present embodiment can be applied to either of a contact hole and a via hole.

Third Embodiment

FIG. 3 is a cross-sectional view of a structure before being subjected to W-CMP, showing a semiconductor device according to a third embodiment of the present invention. As shown in FIG. 3, reference numeral 1 designates a lower interconnection; 2 designates an interlayer dielectric film; 13 designates a impurity-doped titanium (Ti) film; 4 designates a TiN film; and 5 designates a tungsten (W) film.

The W plug structure shown in FIG. 3 is formed through the following processes. Specifically, after the interlayer dielectric film 2 has been formed on the lower interconnection 1, a hole is formed in the interlayer dielectric film 2 by means of dry etching. The Ti film 13 and the TiN film 4 are formed in sequence from the interlayer dielectric film 2, as barrier metal film, on the interlayer dielectric film 2 including the hole. The W film 5 is deposited on the Ti film 13 and the TiN film 4 so as to fill the hole.

In the present embodiment, when being formed as barrier metal film, the Ti film 13 is doped with impurities such as C, N, O, or Cl. Approaches to forming barrier metal film are divided into sputtering and CVD. When sputtering is employed, a trace amount of impurity gas (an organic gas, N₂, O₂, or Cl₂) is introduced into a chamber at the time of formation of Ti, thereby forming the impurity-doped Ti film 13. When the CVD technique is employed, an impurity gas (an organic gas, N₂, O₂, or Cl₂) is introduced during deposition of a Ti film. Alternatively, a film growth temperature is set to a comparatively low level, and a TiₓCl_{y} gas is introduced into the chamber, thereby forming a Ti film 13 including residual Cl.

In the third embodiment, the Ti film 13 is doped with impurities, such as C, N, O, or Cl, at the time of formation of barrier metal film, thereby forming an impurity-doped Ti film 13. Accordingly, there can be prevented elution of the Ti film 3, which would otherwise be caused by HF cleansing performed after W-CMP, and occurrence of a clearance or void, which would otherwise arise around the W plug. The present embodiment can be applied to either of a contact hole and a via hole.

Fourth Embodiment

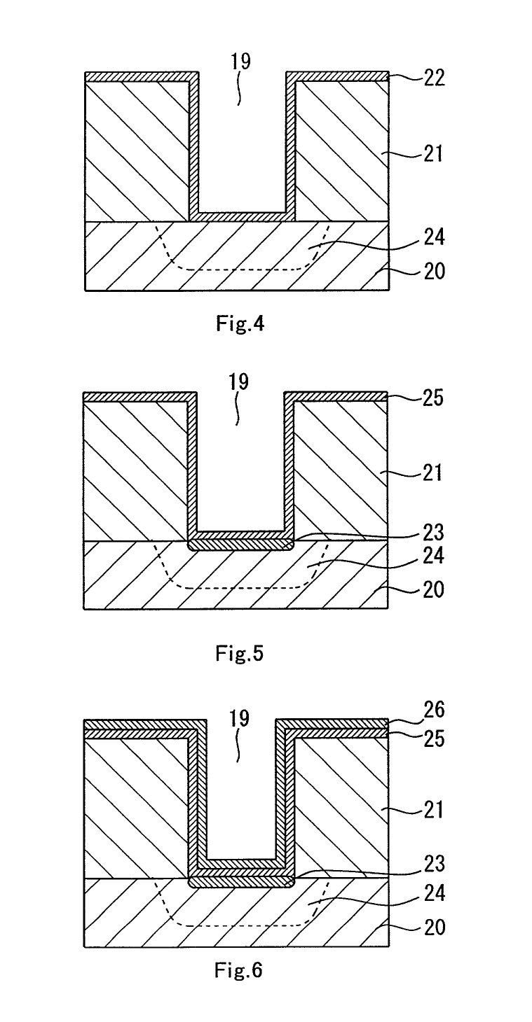

FIGS. 4 through 7 show a semiconductor device according to a fourth embodiment of the present invention. FIG. 4 is a cross-sectional view showing a diffused contact section, in which a Ti film is formed after opening of a contact hole. As shown in FIG. 4, reference numeral 19 designates a contact hole; 20 designates a silicon (Si) substrate (a lower conductive layer); 21 designates an interlayer dielectric film; 22 designates a Ti film; and 24 designates a diffusion layer.

The plug structure shown in FIG. 4 is formed through the following processes. Specifically, after the interlayer dielectric film 21 has been formed on the Si substrate 20, a contact hole 19 is formed in the interlayer dielectric film 21 by means of dry etching. The Ti film 22 is formed, as barrier metal film, on the interlayer dielectric film 21 including the contact hole 19. In this way, the structure shown FIG. 4 is formed.

Subsequently, the structure is subjected to annealing in an N₂ or NH₃ atmosphere, thereby causing silicidation of a contact portion between the Ti film 22 and the substrate 20 (or the diffusing layer 24). The entirety of the portion of the Ti film 22 remaining in contact with the contact hole 19 is nitrided. FIG. 5isacross-sectionalviewshowingtheresultant structure. As shown in FIG. 5, reference numeral 19 designates a contact hole; 20 designates an Si substrate; 21 designates an interlayer dielectric film; 23 designates the silicided TiSi film; 24 designates a diffusion layer; and 25 designates a nitrided TiN film.

If the thus-formed TiN film 25 is found to have an insufficient barrier characteristic, a TiN film 26 is further formed over the TiN film 25, as shown in FIG. 6, thereby increasing the thickness of the TiN film. As shown in FIG. 6, reference numeral 19 designates a contact hole; 20 designates an Si substrate; 21 designates an interlayer dielectric film; 23 designates a TiSi film; 24 designates a diffusion layer; 25 designates a TiN film; and 26 designates an additional TiN film.

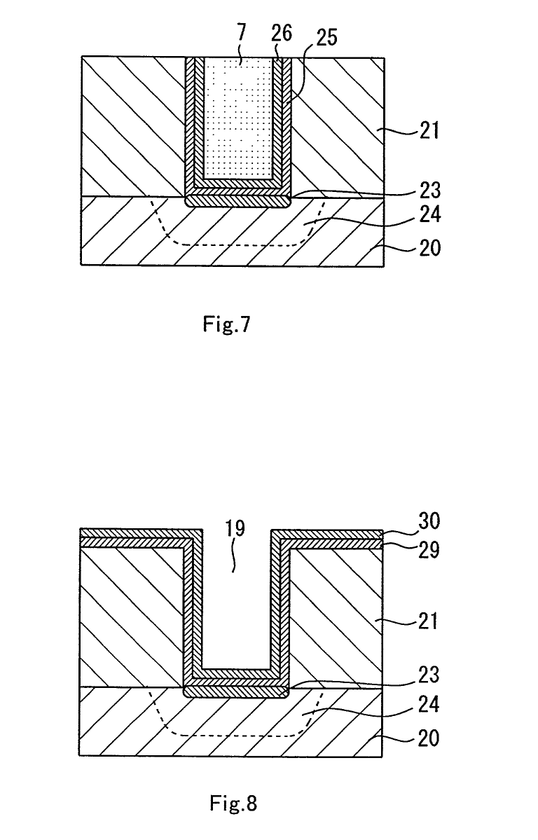

A W film is deposited on the TiN film 26 by means of W-CVD so as to embed the contact hole 19. An excessive W film is removed through abrasion by means of W-CMP, whereby a W film 7 is left in the contact hole 19. Thus, a W plug is formed. FIG. 7 shows the cross section of the W plug immediately after W-CMP. As shown in FIG. 7, reference numeral 7 designates a smoothed W film; 20 designates an Si substrate; 21 designates an interlayer dielectric film; 23 designates a TiSi film; 24 designates a diffusion layer; 25 designates a TiN film; and 26 designates an additional TiN film.

In the fourth embodiment, the structure is subjected to annealing in an N₂ or NH₃ atmosphere after the Ti film 22 has been deposited, so that the TiSi film 23 is formed in the contact portion between the Ti film 22 and the diffusing layer 24. Accordingly, diffusion contact resistance can be diminished. Further, the entirety of portion of the Ti film 22 facing the contact hole 19 is nitrided, thereby forming the TiN film 25. As a result, exposure of the Ti film on the surface can be prevented. Accordingly, there can be prevented elution of the Ti film, which would otherwise be caused by HF cleansing performed after W-CMP, and occurrence of a clearance or void, which would otherwise arise around the W plug. If the TiN film 25 has an insufficient barrier characteristic, the TiN film 26 is additionally laid on the TiN film 25, thus increasing the thickness of the TiN film. Thus, a sufficient barrier characteristic can be sustained.

The present embodiment has described the contact hole 19. In connection with a via hole, after the Ti film 22 has been deposited, the silicon substrate 20 is subjected to N₂ or NH₃ plasma processing, thereby nitriding the Ti film 22 to the TiN film 25. If the TiN film 25 has an insufficient barrier characteristic, the TiN film 26 is further formed on the TiN film 25.

Fifth Embodiment

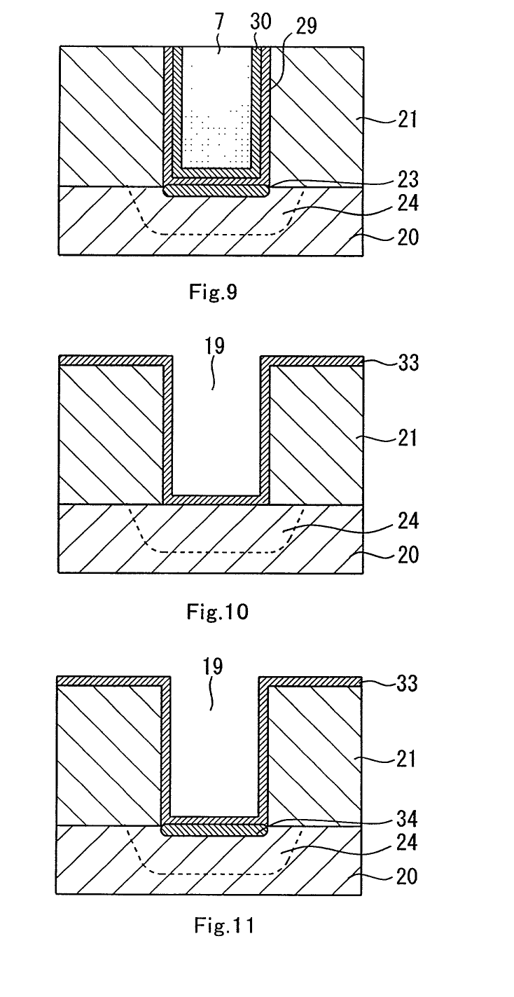

FIGS. 8 and 9 show a semiconductor device according to a fifth embodiment of the present invention. FIG. 8 is a cross-sectional view showing a contact hole section which has been formed by opening a contact hole, forming a Ti film in the contact hole, and forming a TiN film on the Ti film by means of CVD. As shown in FIG. 8, reference numeral 19 designates a contact hole; 20 designates an Si substrate; 21 designates an interlayer dielectric film; 23 designates a TiSi film; 24 designates a diffusion layer; 29 designates a TiN film which has been nitrided during deposition of a TiN film by means of CVD; and 30 designates a TiN film formed by means of CVD.

The structure shown in FIG. 8 is formed through the following processes. After the interlayer dielectric film 21 has been formed on the Si substrate 20, the contact hole 19 is formed in the interlayer dielectric film 21 by means of dry etching. A Ti film is formed, as barrier metal film, on the interlayer dielectric film 21 including the contact hole 19 (see FIG. 4).

Subsequently, the structure is subjected to CVD in an N₂ or NH₃ atmosphere, thereby causing silicidation of a contact portion between the Ti film and the substrate 20. As a result, a silicided TiSi film 23 is formed in the contact portion between the Ti film and the substrate 20. The entirety of the portion of the Ti film remaining in contact with the contact hole 19 is nitrided. Thus, there is formed a TiN film 29 (see FIG. 5). If the thus-formed TiN film 29 has an insufficient barrier characteristic, a TiN film 30 is formed additionally on the TiN film 29 by means of CVD, thus increasing the thickness of the TiN film. As a result, there is formed a structure shown in FIG. 8.

When a Ti film is formed at a high temperature (of 500° C. or more) by means of CVD using an N₂ or NH₃ gas through the foregoing processes, the contact portion between the Ti film and the diffusing layer 24 becomes silicided, thereby enabling a reduction in contact resistance. Further, a lower Ti film is nitrided into a TiN film 29. As a result, no Ti film is exposed on the surface after W-CMP, thereby preventing occurrence of a clearance or void around the W plug.

As mentioned above, when the TiN film 29 is formed at a temperature of 500° C. or more by means of CVD, the contact portion between the Ti film and the diffusing layer 24 becomes silicided into the TiSi film 23. Hence, at the time of deposition of the TiN film 29 by means of CVD, only nitriding of a TiN film is effected.

FIG. 9 is a cross-sectional view showing a W plug after W-CMP. As shown in FIG. 9, reference numeral 7 designates a smoothed W film; 20 designates an Si substrate; 21 designates an interlayer dielectric film; 23 designates a TiSi film; 24 designates a diffusion layer; 29 designates a TiN film which has become nitrided during deposition of a TiN film by means of CVD; and 30 designates a TiN film formed by means of CVD.

In connection with a via hole formed in a lower interconnection through use of an Al alloy, the TiN film 29 cannot be formed at a high temperature. For this reason, the TiN film 29 must be formed by means of plasma CVD at a temperature of less than 500° C. In this case, a Ti film is nitrided by mean of activated atoms of N₂ or NH₃ developing in plasma. Thus, even in the case of formation of the via hole, there can be prevented occurrence of a clearance or void around a W plug, which would otherwise be caused by HF cleansing.

Sixth Embodiment

FIGS. 10 through 14 show a semiconductor device according to a sixth embodiment of the present invention. FIG. 10 is a cross-sectional view showing a contact hole section which has been formed by opening a contact hole and forming a Ti or Co (cobalt) film in the contact hole. As shown in FIG. 10, reference numeral 19 designates a contact hole; 20 designates an Si substrate; 21 designates an interlayer dielectric film; 24 designates a diffusion layer; and 33 designates a (TiN)/Ti film or (TiN)/Co film [(TiN) means that a TiN film may be formed in addition to a Ti film or a Co film].

The structure shown in FIG. 10 is formed through the following processes. After the interlayer dielectric film 21 has been formed on the Si substrate 20, the contact hole 19 is formed in the interlayer dielectric film 21 by means of dry etching. A (TiN)/Ti film or (TiN)/Co film 33 is formed, as barrier metal film, on the interlayer dielectric film 21 including the contact hole 19. As a result, there is formed a structure shown in FIG. 10.

Subsequently, the structure is subjected to annealing in an N₂ or NH₃ atmosphere. As a result, a contact portion between the (TiN)/Ti film or (TiN)/Co film 33 and the diffusing layer 24 is caused to be silicided. FIG. 11 is a cross-sectional view of a resultantly-obtained structure. As shown in FIG. 11, reference numeral 19 designates a contact hole; 20 designates an Si substrate; 21 designates an interlayer dielectric film; 24 designates a diffusion layer; 33 designates a (TiN)/Ti film or (TiN)/Co film; and 34 designates a silicided TiSi or CoSi film.

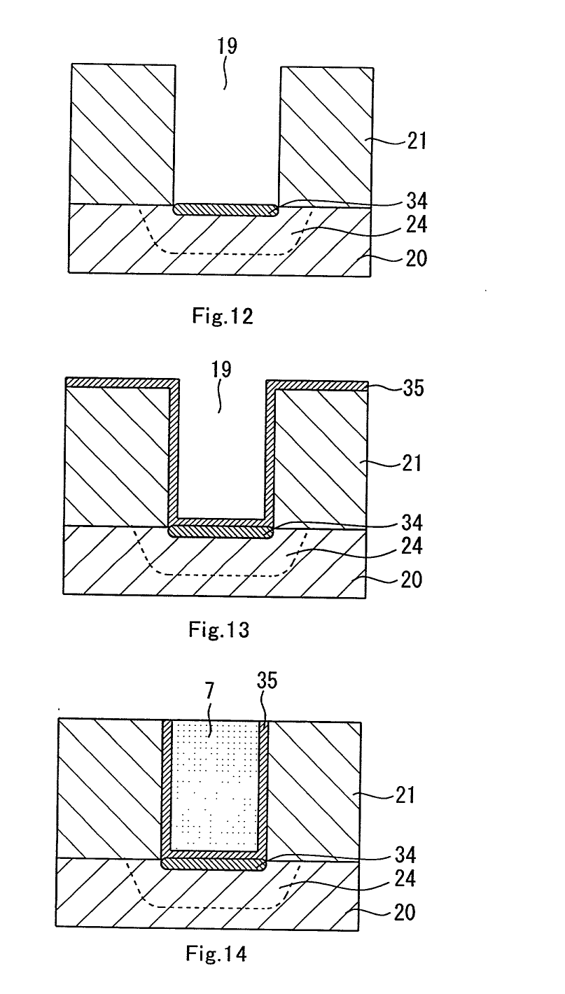

The (TiN)/Ti or (TiN)/Co film 33 which has remained unreacted through the annealing treatment shown in FIG. 11 is removed by means of wet treatment, thereby leaving the TiSi or CoSi film 34 in the bottom of the contact hole 19. FIG. 12 shows the thus-formed TiSi or CoSi film 34. As shown in FIG. 12, reference numeral 19 designates a contact hole; 20 designates an Si substrate; 21 designates an interlayer dielectric film; 24 designates a diffusion layer; and 34 designates a TiSi or CoSi film.

A TiN film is formed on the interlayer dielectric film 21 including the contact hole 19. FIG. 13 shows the cross section of the contact hole section at this time. As shown in FIG. 13, reference numeral 19 designates a contact hole; 20 designates an Si substrate; 21 designates an interlayer dielectric film; 24 designates a diffusion layer; 34 designates a TiSi or CoSi film; and 35 designates a TiN film.

Subsequently, a W film is deposited on the TiN film 35 by means of W-CVD so as to embed the contact hole 19. An excessive W film is removed through abrasion by means of W-CMP, whereby a W film 7 is left in the contact hole 19. Thus, a W plug is formed. FIG. 14 shows the cross section of the W plug immediately after W-CMP. As shown in FIG. 14, reference numeral 7 designates a smoothed W film; 20 designates an Si substrate; 21 designates an interlayer dielectric film; 24 designates a diffusion layer; 34 designates a TiSi or CoSi film; and 35 designates a TiN film.

As shown in FIG. 14, even in the present embodiment, there can be prevented exposure of the Ti film on the surface, which would otherwise be caused as a result of formation of a W plug. Accordingly, there can be prevented occurrence of a clearance or void, which would otherwise arise around the W plug as a result of HF cleansing. Further, the TiSi or CoSi film 34 is formed in the contact portion between the (TiN)/Ti film or (TiN) /Co film 33 and the diffusing layer 24, thereby diminishing contact resistance.

In the present embodiment, when a CoSi film has already been formed on the diffusion layer 24 before the contact hole 19 is opened, the TiN film 35 is formed immediately after opening of the contact hole 19. There can be prevented occurrence of a clearance or void, which would otherwise arise around the W plug as a result of HF cleansing.

Seventh Embodiment

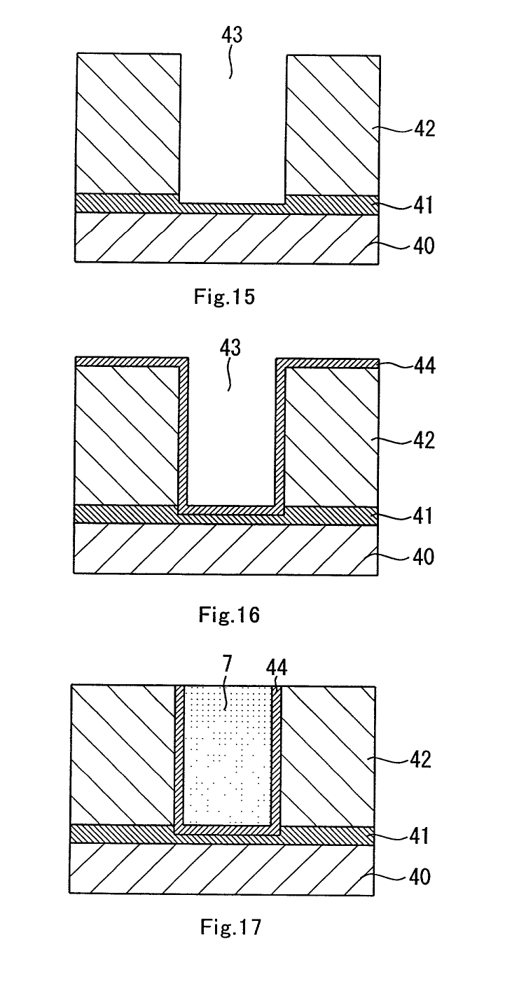

FIGS. 15 through 17 show a semiconductor device according to a seventh embodiment of the present invention. FIG. 15 is a cross-sectional view showing a via hole section after opening of a via hole. As shown in FIG. 15, reference numeral 40 designates an Al alloy (a lower conductive layer); 41 designates a TiN film serving as an anti-reflection film; 42 designates an interlayer dielectric film; and 43 designates a via hole.

The structure shown in FIG. 15 is formed in accordance with the following processes. First, the Ti film 41 and the interlayer dielectric film 42 are deposited on the Al alloy 40 in sequence therefrom. The via hole 43 is formed in the TiN film 41 and the interlayer dielectric film 42 by means of dry etching. As shown in FIG. 15, etching of the via hole 43 is effected such that the etching is stopped at any position within the TiN film 41 so as not to reach the Al alloy 40.

A TiN film is formed on the interlayer dielectric film 42 including the via hole 43. FIG. 16 shows the cross section of the via hole section. As shown in FIG. 16, reference numeral 40 designates an Al alloy; 41 designates a TiN film serving as an anti-reflection film; 42 designates an interlayer dielectric film; 43 designates a via hole; and 44 designates a TiN film.

Subsequently, a W film is deposited on the TiN film 44 by means of W-CVD so as to embed the via hole 43. An excessive W film is removed through abrasion by means of W-CMP, whereby a W film 7 is left in the via hole 43. Thus, a W plug is formed. FIG. 17 shows the cross section of the W plug immediately after W-CMP. As shown in FIG. 17, reference numeral 7 designates a smoothed W film; 40 designates an Al alloy; 41 designates a TiN film serving as an antireflection film; 42 designates an interlayer dielectric film; and 44 designates a TiN film.

In a case where the via hole 43 has reached the Al alloy 40 as a result of etching, if the TiN film 44 is formed after opening of the via hole 43, the Al alloy 40 is deteriorated, thereby resulting in an increase in the resistance of the via hole. Under normal conditions, a Ti film serving as barrier metal film must be interposed between the Al alloy 40 and the TiN film 44. However, if etching of the via hole 43 is effected such that etching is stopped at any position within the TiN film 41 serving as an antireflection film so as not to reach the Al alloy 40, insertion of a Ti film which is to serve as barrier metal film is not necessary.

Thus, the TiN film 44 can be formed immediately after opening of the via hole 43. Accordingly, exposure of the Ti film on the surface can be prevented. When deposition of a W film and abrasion of the W film utilizing W-CMP are effected, there can be prevented occurrence of a clearance or void, which would otherwise arise around the W plug as a result of HF cleansing.

The previously-described embodiments have described merely specific examples of the manner in which the present invention is to be implemented, and these embodiments shall not impose any limitation on interpretation of the technical scope of the present invention. The present invention can be carried out in various forms without departing from the spirit or primary characteristics of the present invention.

Since the present invention has been embodied in the manner as mentioned above, the invention yields the following advantages.

A portion or the entirety of barrier metal film to be formed in a hole formed in an interlayer dielectric film on a substrate is formed from metal material, other than elemental titanium, possessing elution resistance against hydrofluoric acid. There can be prevented elution of a titanium film, which would otherwise be caused by HF cleansing, and occurrence of a clearance or void, which would otherwise arise around a conductive plug.

Particularly, when exposure of a titanium film on the surface is prevented by means of nitriding barrier metal film, the surface of the interlayer dielectric film is also nitrided. As a result, there can be prevented etching of an interlayer dielectric film, which would otherwise be caused during HF cleansing. Thus, extension of etching to the portion of a titanium film which is not nitrided can be prevented. There can be prevented occurrence of a clearance or void, which would otherwise arise around a conductive plug.

After a titanium or cobalt film has been formed as barrier metal film in a hole, the film is subjected to annealing, plasma processing, or CVD. As a result, the contact portion between the titanium or cobalt film, formed at the bottom of the barrier metal film, and the substrate is caused to be silicided, thereby enabling a reduction in the resistance of a via hole and that of a contact hole.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2001-009460, filed on Jan. 17, 2001 including specification, claims, drawings and summary, on which the Convention priority of the present application is based, are incorporated herein by reference in its entirety.

What is claimed is:

1. A semiconductor device comprising:
a substrate;
an interlayer dielectric film formed on or above the substrate;
a lower conductive layer formed in or on the substrate under or below the interlayer dielectric film;
a conductive plug formed to embed a connection hole being formed in the interlayer dielectric film; and
a barrier metal film formed between the conductive plug and the interlayer dielectric film and between the conductive plug and the lower conductive layer;
wherein at least a portion of the barrier metal film is formed from metal having elution resistance against hydrofluoric acid.

2. The semiconductor device according to claim 1, wherein at least the portion of the barrier metal film is formed from titanium oxide.

3. The semiconductor device according to claim 1, wherein at least the portion of the barrier metal film is formed from titanium nitride.

4. The semiconductor device according to claim 1, wherein at least the portion of the barrier metal film is formed from impurity-doped titanium.

5. The semiconductor device according to claim 1, wherein a contact portion between the barrier metal film and the lower conductive layer is formed from silicide.

6. The semiconductor device according to claim 5, wherein the contact portion between the barrier metal film and the lower conductive layer is formed from silicide composed of silicon and titanium.

7. The semiconductor device according to claim 5, wherein the contact portion between the barrier metal film and the lower conductive layer is formed from silicide composed of silicon and cobalt.

8. The semiconductor device according to claim 5, wherein at least the portion of the barrier metal film is formed from titanium oxide.

9. The semiconductor device according to claim 5, wherein at least the portion of the barrier metal film is formed from titanium nitride.

10. The semiconductor device according to claim 5, wherein at least the portion of the barrier metal film is formed from impurity-doped titanium.

11. A semiconductor device comprising:
a substrate;
an antireflection film formed on or above the substrate;
an interlayer dielectric film formed on the antireflection film;
a lower conductive layer formed in or on the substrate under or below the antireflection film;
a conductive plug formed to embed a connection hole being formed in the antireflection film and the interlayer dielectric film; and
a barrier metal film formed between the conductive plug and the antireflection film and between the conductive plug and the interlayer dielectric film;
wherein the bottom of the connection hole is formed within the antireflection film, and at least a portion of the barrier metal film is formed from metal having elution resistance against hydrofluoric acid.

12. The semiconductor device according to claim 11, wherein at least the portion of the barrier metal film is formed from titanium oxide.

13. The semiconductor device according to claim 11, wherein at least the portion of the barrier metal film is formed from titanium nitride.

14. The semiconductor device according to claim 11, wherein at least the portion of the barrier metal film is formed from impurity-doped titanium.
